(19) United States
(12) Patent Application Publication
(10) Pub. No.: US 2025/0034451 A1
(43) Pub. Date: Jan. 30, 2025

(54) BORON-CONTAINING COMPOUND AND ORGANIC LIGHT-EMITTING DIODE

(71) Applicant: FLASK CORPORATION, Yonezawa-shi (JP)

(72) Inventor: Masahiro IGARASHI, Yonezawa-shi (JP)

(21) Appl. No.: 18/663,222

(22) Filed: May 14, 2024

(30) Foreign Application Priority Data
Jul. 12, 2023 (JP) 2023-114662

(51) Int. Cl. C09K 11/06; H10K 50/11

(52) U.S. Cl. CPC C09K 11/06; H10K 50/11; C09K 2211/1022

(57) ABSTRACT

Provided is a boron-containing compound as material for blue LED and an OLED. The boron-containing compound has structure of formula (1):

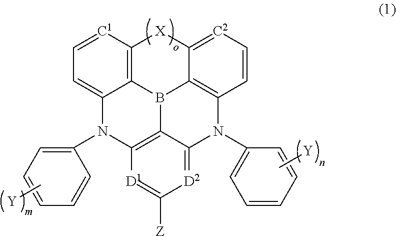

X is —BAr—, —CR¹R²—, —NAr—, —O—, —SiR³R⁴— or —S— wherein Ar is an aryl group; R¹ to R⁴ are independently hydrogen, an alkyl group having 1 to 6 carbons, an alkoxy group having 1 to 6 carbons, amino group or an aryl group having 5 to 30 core atoms, and R¹ and R², or R³ and R⁴ may join to form a ring; o is 1 or 2; C¹ and C² each are carbon or an aryl carbon and may form a ring with X and the neighboring carbon; Y is fluorine; 0≤m+n≤10 wherein m and n are 0 to 5; D¹ and D² are independently carbon or nitrogen; Z is hydrogen, an alkyl group having 1 to 6 carbons, an alkoxy group having 1 to 6 carbons, fluorine or amino group.

### BACKGROUND OF THE INVENTION

### Field of the Invention

The present invention relates to an organic light-emitting diode having a light-emitting layer including a boron-containing compound as dopant material.

### Description of the Related Art

It is necessary to improve the luminous efficiency to put an organic light-emitting diode (OLED) to practical use. Excitons which organic compounds form include fluorescence from singlet excitons (S₁) and phosphorescence from triplet excitons (T₁). But a statistical ratio of fluorescence and phosphorescence formed in the EL device is E_{S1}:E_{T1}=1:3, so that the internal quantum efficiency is limited to 25% for the OLED that uses fluorescence.

OLEDs have been recently developed making use of thermally activated delayed fluorescence (TADF) material, that is, convertible material to radiate a part of triplet excited state, which is used for up-conversion from the lowest triplet excited state (T₁) to the lowest singlet excited state (S₁). The TADF material is designed to make the energy difference ΔE_{ST} between the lowest excited singlet state (S₁) and the lowest excited triplet state (T₁) small in order to facilitate transition between S₁ and T₁ states (reverse intersystem crossing) and thereby to emit fluorescence by radiative deactivation of the lowest excited singlet state. The TADF material exerts higher luminous efficiency than ordinary luminescent materials, because the triplet exciton energy (E_{T1}) with higher formation ratio is converted to the singlet exciton (S₁) by reverse intersystem crossing and contributes to enhancing the fluorescence emission.

Research and development has been eagerly carried out on the TADF materials, because they are anticipated to achieve high luminous efficiency. But only a few of the TADF materials ever developed are found to emit good blue light.

The luminous efficiency of a light-emitting layer can be improved upon not only by the improvement of light-emitting materials but also by the combined use of host materials that confine the energy to molecules of the light-emitting materials. For example, when the light-emitting material is a blue light-emitting dopant, a host material that is to be combined needs to have more highly excited state energy levels, because the dopant itself has a highly excited state energy level. Since the light-emitting layer is made of the above-mentioned dopant and host materials, excitons can be efficiently formed from the injected charge in the host, which successfully achieves high-efficiency luminescence.

As an example of dopant and host materials for use in a light-emitting layer, Japanese Unexamined Patent Application Publication (Translation of PCT Application) No. 2009-512628 discloses benzoquinolizinoacridine derivatives which work as dopant in a light-emitting layer and as hole transport material in a hole transport layer of a blue light-emitting diode. According to Japanese Unexamined Patent Application Publication (Translation of PCT Application) No. 2012-507507, nitrogen-containing heterocyclic compounds are used as host in a light-emitting layer and also used in a hole transport layer or in a hole-injection layer.

WO 2011/143563 discloses the use of an azaborine derivative having a nitrogen atom and a boron atom at 1,4-position as host in phosphorescent OLED. With attention being paid to the charge transfer and high light emission characteristics originated from a boron, and lone pairs of an oxygen, a nitrogen or a sulfur atom, WO 2017/18326, Japanese Unexamined Patent Publication No. 2017-126606 and WO 2017/195669 disclose that the conjugated boron compounds having any of these atoms contribute to the charge transfer and high light emission characteristics and provides successfully an OLED excellent in luminous efficiency and stability at high temperature.

Besides azaborine derivatives, namely conjugated boron compounds having oxygen atoms, nitrogen atoms or sulfur atoms, Japanese Unexamined Patent Publication No. 2018-43984 discloses aromatic heteropolycyclic compounds, such as a conjugated boron compound in which a boron atom is replaced with a phosphorus atom, a phosphoryl group, a thiophosphoryl group, a silicon atom, a bismuth atom, a germanium atom and so on.

WO 2018/159662 discloses that the light-emitting material, which has intramolecular donor and acceptor moieties, emits TADF and realizes intramolecular proton transfer, has sufficiently high quantum efficiency for practical use, so that it is suitable for OLED light-emitting materials.

In addition to the above, there are other reports on light-emitting materials for use in OLED: Japanese Unexamined Patent Publication No. 2020-123721 discloses blue light-emitting polycyclic aromatic compounds having a boron atom, nitrogen atoms and/or oxygen atoms. Chinese Unexamined Patent Application Publication No. 113801151 discloses a compound the coronene moiety of which is partly replaced with a boron atom and a sulfur atom. WO 2020/108899 discloses a heterocyclic compound having one boron atom and two atoms of oxygen or nitrogen arranged to face the boron atom. Japanese Unexamined Patent Application Publication (Translation of PCT Application) No. 2022-527591 discloses a heterocyclic compound having one nitrogen atom and two boron atoms arranged to face the nitrogen atom.

### BRIEF SUMMARY OF THE INVENTION

An object of the present invention is to provide a novel blue light-emitting boron-containing compound, and also to provide an OLED with high luminous efficiency, long life and durability including the boron-containing compound.

A boron-containing compound of the present invention has a structure represented by the following general formula (1).

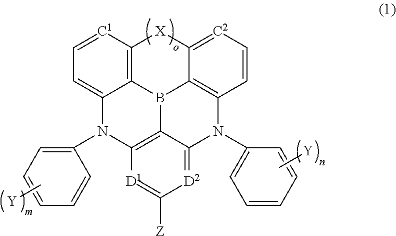

In the general formula (1), X is —BAr—, —CR¹R₂—, —NAr—, —O—, —SiR³R⁴— or —S—. Ar is an aryl group. R¹, R², R³ and R⁴ are each independently a hydrogen atom, an alkyl group having 1 to 6 carbon atoms, an alkoxy group having 1 to 6 carbon atoms, an amino group or an aryl group having 5 to 30 core atoms. R¹ and R², or R³ and R⁴ may join each other to form a ring. o is 1 or 2. C¹ and C² are each a carbon atom or an aryl carbon atom and may form a ring with X and the neighboring carbon atom together. Y is a fluoro group; 0≤m+n≤10 wherein m and n are an integer of 0 to 5. D¹ and D² are each independently a carbon atom or a nitrogen atom. Z is a hydrogen atom, an alkyl group having 1 to 6 carbon atoms, an alkoxy group having 1 to 6 carbon atoms, a fluoro group or an amino group.

Preferably in the general formula (1), D¹ and D² both are carbon atoms; Y is a fluoro group; 1≤m+n≤10 wherein m and n are an integer of 0 to 5; and Z is an alkyl group having 1 to 6 carbon atoms, an alkoxy group having 1 to 6 carbon atoms, a fluoro group or an amino group.

Preferably in the general formula (1), at least one of D¹ and D² is a nitrogen atom; Y is a fluoro group; 0≤m+n≤10 wherein m and n are an integer of 0 to 5; and Z is a hydrogen atom.

An OLED of the present invention comprises the boron-containing compound.

An OLED of the present invention comprises the boron-containing compound in the light-emitting zone.

An OLED of the present invention comprises the boron-containing compound in the light-emitting layer.

An OLED comprising 0.1 to 20 wt % of the boron-containing compound in the light-emitting layer.

The boron-containing compound of the present invention is a novel compound with a condensed heterocyclic structure including a boron atom and nitrogen atoms in the molecule. The novel compound has a large HOMO-LUMO energy gap and high triplet energy (E_{T1}). The boron-containing compound is useful as OLED light-emitting material, because of having a small difference of energy between the triplet excited state (T₁) and the singlet excited state(S₁) and showing thermally activated delayed fluorescence (TADF).

The OLED using the boron-containing compound for blue dopant in the light-emitting layer improves luminous efficiency and lifetime greatly, as compared to the conventional blue light-emitting diodes.

### BRIEF DESCRIPTION OF THE DRAWING

Fig. 1 represents a schematic illustration of cross section of the OLED of one embodiment of the present invention.

### DESCRIPTION OF THE PREFERED EMBODIMENTS

Hereinafter, the present invention will be described in detail.

The boron-containing compound of the present invention has a structure represented by the following general formula (1).

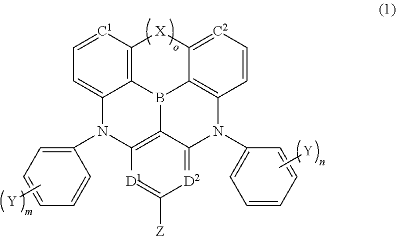

In the general formula (1), X is —BAr—, —CR¹R²—, —NAr—, —O—, —SiR³R⁴— or —S—. o is 1 or 2.

Ar is an aryl group.

R¹ and R² are each independently a hydrogen atom, an alkyl group having 1 to 6 carbon atoms, an alkoxy group having 1 to 6 carbon atoms, an amino group or an aryl group having 5 to 30 core atoms. R¹ and R² may join each other to form a ring.

R³ and R⁴ are each independently a hydrogen atom, an alkyl group having 1 to 6 carbon atoms, an alkoxy group having 1 to 6 carbon atoms, an amino group or an aryl group having 5 to 30 core atoms. R³ and R⁴ may join each other to form a ring.

X is —BAr—, —NAr—, —CR¹R²—, —SiR³R⁴—, an ether bond (—O—), or a sulfide bond (—S—).

In the —NAr— and —BAr—, Ar is an aryl group having 5 to 10 core atoms. Examples of the aryl group having 5 to 10 core atoms are the same as those when any of R¹ to R⁴ is the aryl group having 5 to 10 core atoms.

Specific examples of the —NAᵣ— include a phenylamino group, a naphthylamino group and a pyridinylamino group.

Specific examples of the —BAᵣ— include a phenylboranyl group, a naphthylboranyl group and a pyridinylboranyl group.

In the —CR¹R²—, R¹ and R² are each independently a hydrogen atom, an alkyl group having 1 to 6 carbon atoms, an alkoxy group having 1 to 6 carbon atoms, an amino group, and an aryl group having 5 to 30 core atoms.

In the —SiR³R⁴—, R³ and R⁴ are each independently a hydrogen atom, an alkyl group having 1 to 6 carbon atoms, an alkoxy group having 1 to 6 carbon atoms, an amino group, and an aryl group having 5 to 30 core atoms.

The alkyl group having 1 to 6 carbon atoms represents a linear or a branched alkyl group. Specific examples include a methyl group, an ethyl group, a propyl group, an isopropyl group, a n-butyl group, an isobutyl group, a s-butyl group, a t-butyl group, a n-pentyl group, a neopentyl group, an isopentyl group, a s-pentyl group, a 3-pentyl group, a t-pentyl group, a n-hexyl group, a 2-methylpentyl group, a 3-methylpentyl group, a 2,2-dimethylbutyl group and a 2,3-dimethylbutyl group.

The alkoxy group having 1 to 6 carbon atoms represents a linear or a branched alkoxy group. Specific examples include a methoxy group, an ethoxy group, a propoxy group, an isopropoxy group, a n-butoxy group, an isobutoxy group, a s-butoxy group, a t-butoxy group, a n-pentoxy group, a neopentoxy group, an isopentoxy group, a s-pentoxy group, a 3-pentoxy group, a t-pentoxy group, a n-hexoxy group, a 2-methylpentoxy group, a 3-methylpentoxy group, a 2,2-dimethylbutoxy group and a 2,3-dimethylbutoxy group.

The aryl group having 5 to 30 core atoms represents a monocyclic or condensed polycyclic aromatic hydrocarbyl or heteroaromatic compound group which may have substituents. Specific examples include a phenyl group, a 1-naphthyl group, a 2-naphthyl group, a p-methoxyphenyl group, a p-t-butylphenyl group, a p-tolyl group, a m-tolyl group, an o-tolyl group, a pentafluorophenyl group, a phenanthryl group, a pyrenyl group, a fluorenyl group, a fluoranthenyl group, a pyridyl group, a quinoxalyl group, a pyrrole group, an indolyl group, a carbazolyl group, an imidazolyl group, a benzimidazolyl group, a furanyl group, a benzofuranyl group, a dibenzofuranyl group, a thiophenyl group, a benzothiophenyl group, a dibenzothiophenyl group, a benzoxazolyl group, and a benzothioxazolyl group.

In the —CR¹R²— and —SiR³R⁴—, R¹ and R², and R³ and R⁴ may join each other to form a four- to eight-membered ring, and a five- to six-membered ring preferably. Five- to six-membered rings are cyclopentyl and cyclohexyl groups.

O represents the number of X. o is an integer of 1 or 2.

C¹ and C² are a carbon atom or an aryl carbon atom. More specifically, the aryl carbon atom is a carbon atom with an aryl group having 6 to 10 carbon atoms. One of the favorable aryl groups is a phenyl group.

C¹ and C² may each form a ring with X and the neighboring carbon atom together. For example, they may form a ring represented by the following structural formulae.

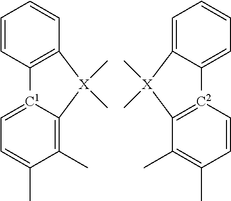

Y is a fluoro group. m+n represents the number of the fluoro groups. m+n is an integer of 0 to 10, and m and n each are an integer of 0 to 5. It is preferable that 1≤m+n≤10 have m and n of an integer of 0 to 5.

D¹ and D² are each independently a carbon atom or a nitrogen atom. Either or both of D¹ and D² may be a carbon atom or a nitrogen atom. But when the carbon atom between D¹ and D² is a nitrogen atom and either or both of D¹ and D² are a nitrogen atom and a carbon atom, blue light emission cannot be obtained.

Z is a hydrogen atom, an alkyl group having 1 to 6 carbon atoms, an alkoxy group having 1 to 6 carbon atoms, a fluoro group, or an amino group. Specific examples of the alkyl group having 1 to 6 carbon atoms and the alkoxy group having 1 to 6 carbon atoms are the same as those when R¹ to R⁴ are the alkyl group having 1 to 6 carbon atoms and the alkoxy group having 1 to 6 carbon atoms.

More specifically, the boron-containing compound of the present invention is represented by the following structural formulae.

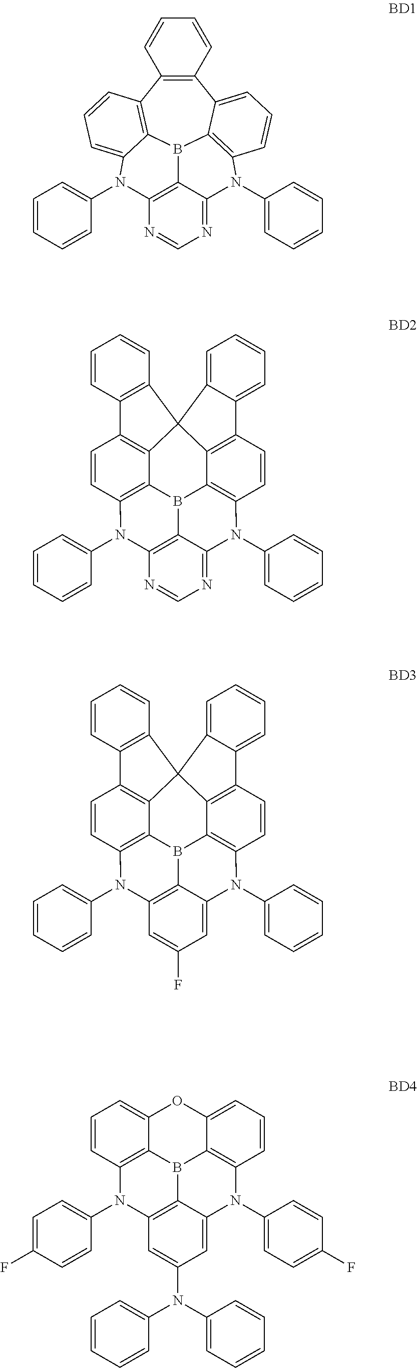 [SMILES: c1ccc(N2c3cccc4c3B3c5c(cccc5N(c5ccccc5)c5ncnc2c53)-c2ccccc2-4)cc1 ; c1ccc(N2c3ccc4c5c3B3c6c2ncnc6N(c2ccccc2)c2ccc6c(c23)C5(c2ccccc2-4)c2ccccc2-6)cc1 ; Fc1cc2c3c(c1)N(c1ccccc1)c1ccc4c5c1B3c1c(ccc3c1C5(c1ccccc1-3)c1ccccc1-4)N2c1ccccc1 ; Fc1ccc(N2c3cccc4c3B3c5c(cccc5N(c5ccc(F)cc5)c5cc(N(c6ccccc6)c6ccccc6)cc2c53)O4)cc1]

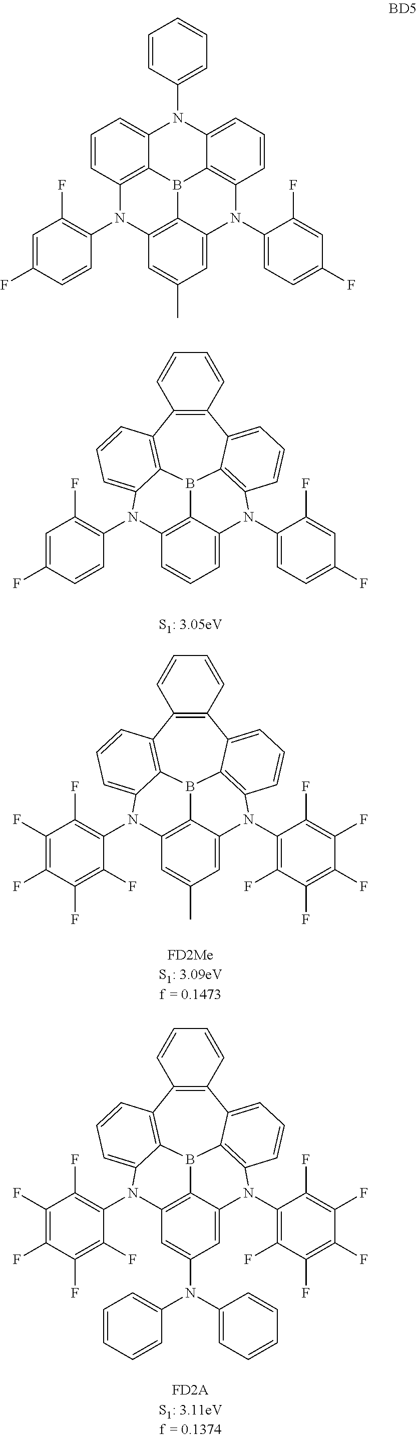

The boron-containing compound of the present invention has an expanded π-conjugated structure. Most of the molecules having π-conjugated systems with light absorption bands in the visible light region, are known to work as pigments. But as π-conjugated systems get expanded, the HOMO increases and the LUMO decreases, which leads to decrease in the HOMO-LUMO gap (band gap E_{g}). In the present invention, however, because of having a boron atom and nitrogen atoms opposite to the boron atom in the aromatic ring as represented by the general formula (1), the boron-containing compound has less aromaticity not to cause decrease in the HOMO-LUMO gap even though π-conjugated system is expanded.

The boron-containing compound of the present invention has high triplet excited energy (E_{T}). In the boron-containing compound, the electronic perturbation of the hetero atom, especially the boron atom causes the localization of SOMO 1 and SOMO 2 in the triplet excited state (E_{T}) and decreases the interorbital exchange interaction. As a result, the boron-containing compound has a small energy gap (ΔE_{ST}) between the singlet(E_{S1}) and triplet (E_{T1}) excited states and shows thermally activated delayed fluorescence (TADF).

Owing to the bulky structure in which the ring structure including a boron atom and nitrogen atoms is enclosed with several aromatic rings, the boron-containing compound of the present invention has a pretty rigid structure that moderately restrains rotation and bending. Such a structure enables the boron-containing compound to have a very small vibrational energy and an emission spectrum of an extremely narrow full width at half maximum, i.e., high color purity even in the S₁-S₀ transition (transition from singlet excited state (S₁) to singlet ground state (Sₒ)) that brings about the torsional vibration of the whole molecule.

As is reported on the already-known organic blue light-emitting diode (DABNA-1), and as far as the boron-containing compound of the present invention is concerned, the stretching vibration is not observed in the S₁-S₀ transition owing to the boron-nitrogen multiple resonance effect.

In the boron-containing compounds of the present invention, FD2Me shows an excitation energy peak S₁ of 3.09 eV in the excitation state (HOMO->LUMO) and the oscillator strength (f) in the S₁-S₀ transition is 0.1473; FD2A shows S₁ is 3.11 eV and that the oscillator strength (f(S₁-S₀)) is 0.1374. As a result, blue light emission spectrum with high color purity is obtained.

In the present invention, examining functional groups to be added to a molecule of the boron-containing compound enables the boron-containing compound to change its electronic properties, which can adjust a band gap E_{g} and make the singlet-triplet energy gap (ΔE_{ST}) as small as possible. The energy once transferred to the triplet excited state (E_{T}) can be returned to the singlet excited state(E_{S}), and high-efficiency blue fluorescence can be extracted.

The boron-containing compound of the present invention can be manufactured by the following method, for example. As an example, the method of preparing the compound BD1, one of the boron-containing compound of the present invention is shown below.

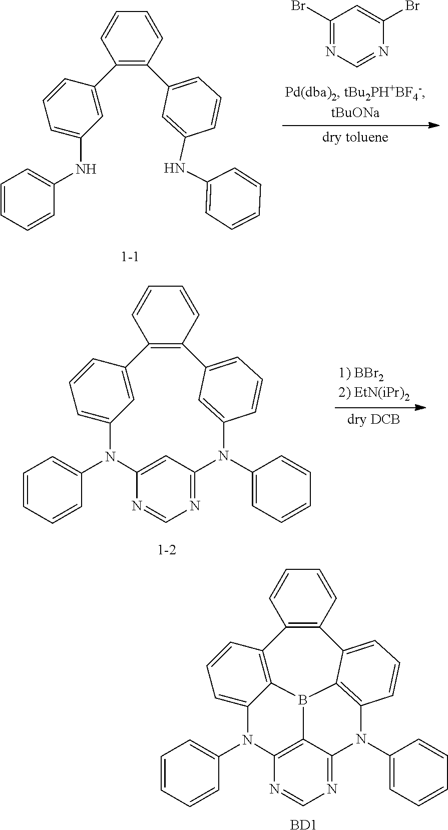

To a four-necked flask, 4.13 g (10 mmol) of the compound 1-1, 2.38 g (10 mmol) of 4,6-dibromopyrimidine, 2.88 g (30 mmol) of sodium tert-butoxide and 1000 ml of dehydrated toluene are added. Then, in a nitrogen atmosphere, 230 mg (0.4 mmol) of bis(dibenzylideneacetone)palladium (0) and 93 mg (0.32 mmol) of tri-tert-butylphosphonium tetrafluoroborate are added thereto and the mixture is refluxed with stirring overnight. The reaction mixture is purified to give 2.20 g (4.5 mmol) of the compound 1-2 in 45% yield.

To a two-necked flask, 1.10 g (2.25 mmol) of the compound 1-2 and 20 ml of dehydrated dichlorobenzene are added. Then 9 ml (9 mmol) of a 1 M solution of boron tribromide is dripped onto the mixture, and the mixture is stirred at a bath temperature of 180° C. for 2 hours. After that, 2.35 ml (13.5 mmol) of diisopropylethylamine is dripped there and the mixture is left stirring for five minutes and then stirred at room temperature for 30 minutes. The mixture is heated up to 120° C. and stirred with heating overnight to complete the reaction. The crude product is purified to give 290 mg (0.58 mmol) of the compound BD1 in 26% yield. The compound BD1 is identified by field desorption mass spectrometry (FD-MS).

It should be noted that the boron-containing compound of the present invention can be prepared by a variety of known methods besides the above method.

The OLED of the present invention is formed by the use of the boron-containing compound. The boron-containing compound is contained in the light-emitting zone of the OLED. The light-emitting zone is where a hole is recombined with an electron to emit light. The light-emitting zone counts as the light-emitting layer 5 in many cases.

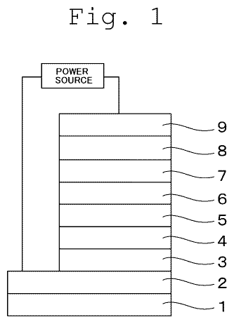

The OLED has a structure in which one or two or more organic layers are stacked between electrodes. Embodiments of the structure include anode 1/hole injection layer 2/hole transport layer 3/light-emitting layer 5/electron transport layer 7/electron injection layer 8/cathode 9, anode 1/hole transport layer 3/light-emitting layer 5/electron transport layer 7/electron injection layer 8/cathode 9, anode 1/hole injection layer 2/light-emitting layer 5/electron transport layer 7/electron injection layer 8/cathode 9, anode 1/hole injection layer 2/hole transport layer 3/light-emitting layer 5/electron injection layer 8/cathode 9, anode 1/hole injection layer 2/hole transport layer 3/light-emitting layer 5/electron transport layer 7/cathode 9, anode 1/light-emitting layer 5/electron transport layer 7/electron injection layer 8/cathode 9, anode 1/hole transport layer 3/light-emitting layer 5/electron injection layer 8/cathode 9, anode 1/hole transport layer 3/light-emitting layer 5/electron transport layer 7/cathode 9, anode 1/hole injection layer 2/light-emitting layer 5/electron injection layer 8/cathode 9, anode 1/hole injection layer 2/light-emitting layer 5/electron transport layer 7/cathode 9, anode 1/light-emitting layer 5/electron transport layer 7/cathode 9, and anode 1/light-emitting layer 5/electron injection layer 8/cathode 9. As shown in FIG. 1, the examples of the present invention demonstrate a structure in which electron barrier layer 4 and hole barrier layer 6 are added to the foregoing structure; that is to say, the structure in which anode 1/hole injection layer 2/hole transport layer 3/electron barrier layer 4/light-emitting layer 5/hole barrier layer 6/electron transport layer 7/electron injection layer 8/cathode 9 are stacked in this order. The organic layers indicate layers except the electrodes 1 and 9, such as the hole injection layer 2, the hole transport layer 3, the electron barrier layer 4, the light-emitting layer 5, the hole barrier layer 6, the electron transport layer 7 and the electron injection layer 8.

Transparent and smooth materials having a total light transmittance of at least 70% or more are used for the substrate. Concretely speaking, the substrate includes flexible transparent substrate, such as glass substrate having a thickness of several microns or special transparent plastic.

Thin films formed on the substrate, such as the anode 1, the hole injection layer 2, the hole transport layer 3, the electron barrier layer 4, the light-emitting layer 5, the hole barrier layer 6, the electron transport layer 7, the electron injection layer 8 and the cathode 9 are formed by a vacuum deposition method or a coating method. When the vacuum deposition method is used, the vapor deposition material is usually heated under a reduced pressure of 10⁻³ Pa or less. Though the film thickness of each layer is different depending on the type of layers or materials used, the anode 1 and the cathode 9 have thicknesses of approximately 100 nm and the other layers including the light-emitting layer 5 have thicknesses of less than 50 nm.

Materials for the anode 1 have high work function and a total light transmittance of generally 80% or more. Concretely speaking, transparent conductive ceramics such as indium tin oxide (ITO) and zinc oxide (ZnO), transparent conductive polymers such as polythiophene-polystyrene sulfonate (PEDOT-PSS) and polyaniline, and other transparent conductive materials are used to make luminescence emitted from the anode 1 pass through.

In order to transport holes from the anode 1 to the light-emitting layer 5 efficiently, the hole injection layer 2 and the hole transport layer 3 are formed between the anode 1 and the light-emitting layer 5.

Hole injection materials constituting the hole injection layer 2 include poly(arylene ether ketone)—containing triphenylamine (KLHIP: PPBI), 1,4,5,8,9,11hexaazatriphenylenehexacarbonitrile (HATCN) and PEDOT-PSS. The hole injection layer 2 made of these materials, which is also called the polymer buffer layer, is effective in lowering the drive voltage of the OLED.

The hole transport layer 3 formed between the anode 1 and the light-emitting layer 5 is a layer which transports holes from the anode 1 to the light-emitting layer 5 efficiently. For the hole transport material, materials having a small ionization energy, i.e., materials which easily excite electrons from the HOMO and generate holes, are used. Examples include poly (9,9-dioctylfluorene-alt-N-(4-butylphenyl)diphenylamine) (TFB), 4,4′-cyclohexylidenebis[N,N-bis(4-methylphenyl)benzenamine] (TAPC), N,N′-diphenyl-N,N′-di(m-tolyl)benzidine (TPD), N,N′-di(1-naphthyl)-N,N′-diphenylbenzidine (NPD), N4, N4″-bis(4-dibenzofuranyl)-N4,N4″, 2′, 3′, 5′, 6′-hexaphenyl-[1,1′:4′,1″-terphenyl]-4,4″-diamine (4DBFHPB), 4,4′,4″-tri-9-carbazolyltriphenylamine (TCTA) and 4,4′,4″-tris[phenyl(m-tolyl)amino]triphenylamine.

It is preferable that light-emitting materials including dopants and hosts be used for the light-emitting layer 5, similarly to other light-emitting layers used for OLEDs.

The boron-containing compound represented by the general formula (1) of the present invention can be used as a dopant.

Preferably, the addition amount of the dopant in the total amount of the dopant and the host is 0.01 to 20 wt %.

Known materials can be widely used for the host, as long as they minimize the charge injection barrier at the hole transport layer 3 and the electron transport layer 7, confine the charge to the light-emitting layer 5, and suppress quenching of the light-emitting exciton. For example, anthracene derivatives having the following structural formulae are used as the host.

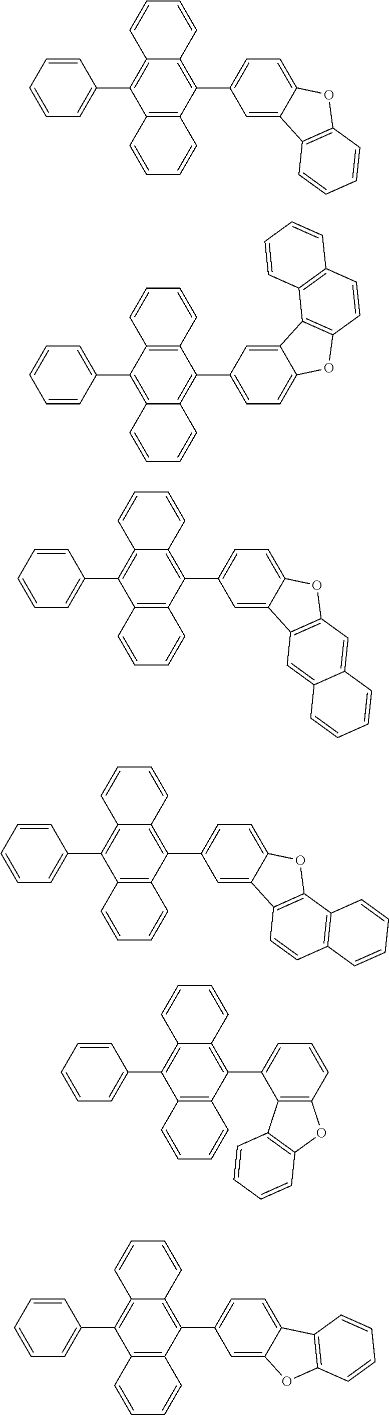

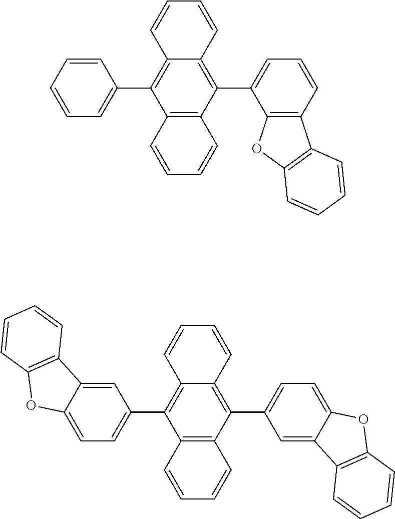 [SMILES: c1ccc(-c2c3ccccc3c(-c3cccc4c3oc3ccccc34)c3ccccc23)cc1 ; c1ccc2c(c1)oc1ccc(-c3c4ccccc4c(-c4ccc5oc6ccccc6c5c4)c4ccccc34)cc12]

Preferably, the addition amount of the host in the total amount of materials for the light-emitting layer 5 is 50 to 99.9 wt %, and further preferably 80 to 95 wt %.

The electron barrier layer 4 can be formed between the light-emitting layer 5 and the hole transport layer 3, as necessary. By inserting the electron barrier layer 4, electrons are confined to the light-emitting layer and the probability of charge recombination in the light-emitting layer is enhanced, which results in high luminous efficiency. Amine derivatives such as bis(biphenyl-4-yl) (3′-(9H-carbazol-9-yl)biphenyl-4-yl) amine are used for the electron barrier material constituting the electron barrier layer 4.

The hole barrier layer 6 and the electron transport layer 7 are formed between the cathode 9 and the light-emitting layer 5 in order to transport electrons efficiently from the cathode 9 to the light-emitting layer 5. Electron transport materials constituting the electron transport layer 7 include 1,4-bis(1,10-phenanthrolin-2-yl)benzene (DPB), 2,9-bis(naphthalen-2-yl)-4,7-diphenyl-1,10-phenanthroline (NBPhen), 8-hydroxyquinolinolatolithium (Liq), 4,6-bis(3,5-di(pyridin-3-yl)phenyl)-2-methylpyrimidine (B3PymPm), 4,6-bis(3,5-di(pyridin-4-yl)phenyl)-2-phenylpyrimidine (B4PyPPm), 2-(4-biphenylyl)-5-(p-t-butylphenyl)-1,3,4-oxadiazole (tBu-PBD), 1,3-bis[5-(4-t-butylphenyl)-2-[1,3,4]oxadiazolyl]benzene (OXD-7), 3-(biphenyl-4-yl)-5-(4-t-butylphenyl)-4-phenyl-4H-1,2,4-triazole (TAZ), bathocuproine (BCP), 1,3,5-tris(1-phenyl-1H-benzimidazol-2-yl)benzene (TPBi) and 3-(4-biphenylyl)-4-phenyl-5-(4-t-butylphenyl)-1,2,4-triazole (TAZ). Among these, the mixed layer of DPB and Liq, etc., are preferable.

The hole barrier layer 6 is a layer to improve the luminous efficiency, where holes are confined in the light-emitting layer 5 and the probability of charge recombination in the light-emitting layer 5 is enhanced. Benzothiophen-triphenyltriazine (DBT-TRZ), 1-(3′-(4-dibenzofuran-4-yl)bipenyl-3-yl)-3,5-diphenyltriazine and so on are used as the hole barrier material constituting the hole barrier layer 6. The hole barrier layer 6 and the electron transport layer 7 have thicknesses of generally 3 to 50 nm, being subject to change depending on the intended design.

Electron injection materials constituting the electron injection layer 8 include lithium fluoride (LiF) and lithium 2-hydroxy-(2,2′)-bipyridyl-6-yl phenolate (Libpp).

Chemically stable materials having low work function of 4 eV or less are used for the cathode 9. Concretely, Al, Al-alkali metal alloy (e.g., Al—Li), Al—Ca alloy, MgAg alloy and so on are used for cathode materials. Thin films of these cathode materials are prepared by resistance heating evaporation, electron beam evaporation, sputtering, or ion plating, for example.

### EXAMPLES

Hereinafter, the present invention will be described in detail with reference to examples, but the present invention is not restricted to the examples.

### Synthesis of the Boron-Containing Compound

### Example 1

### Synthesis of the Boron-Containing Compound BD1

### (i) Synthesis of the Compound 1-2

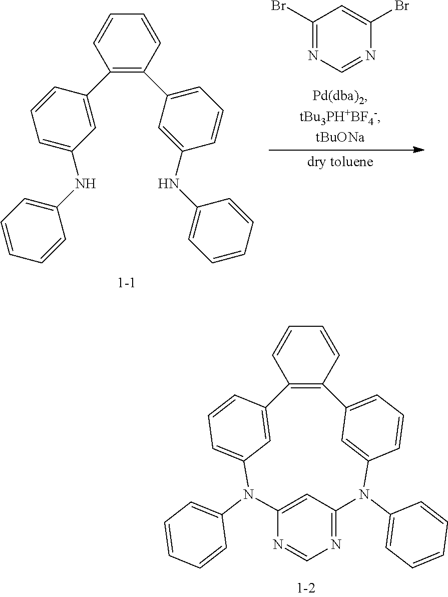 [SMILES: c1ccc(Nc2cccc(-c3ccccc3-c3cccc(Nc4ccccc4)c3)c2)cc1 ; Brc1cc(Br)ncn1 ; c1ccc(N2c3cccc(c3)-c3ccccc3-c3cccc(c3)N(c3ccccc3)c3cc2ncn3)cc1]

To a 1000 mL four-necked flask with a nitrogen introduction pipe on were added 4.13 g (10 mmol) of the compound 1-1, 2.38 g (10 mmol) of 4,6-dibromopyrimidine, 2.88 g (30 mmol) of sodium tert-butoxide and 1000 ml of dehydrated toluene, and the mixture was bubbled with nitrogen for 1 hour. After 230 mg (0.4 mmol) of bis(dibenzylideneacetone)palladium (0) and 93 mg (0.32 mmol) of tri-tert-butylphosphonium tetrafluoroborate were added thereto, the mixture was refluxed with stirring overnight. Thin-layer chromatography (TLC) confirmed the disappearance of the starting materials in the reaction mixture. The reaction mixture was extracted with toluene, and the resulting extract was washed with brine and dried with MgSO₄. The solvent was removed by evaporation, and the residue was purified by silica gel column chromatography to give 2.20 g (4.5 mmol) of the compound 1-2 in 45% yield.

### (ii) Synthesis of the Compound BD1 (Boron-Containing Compound)

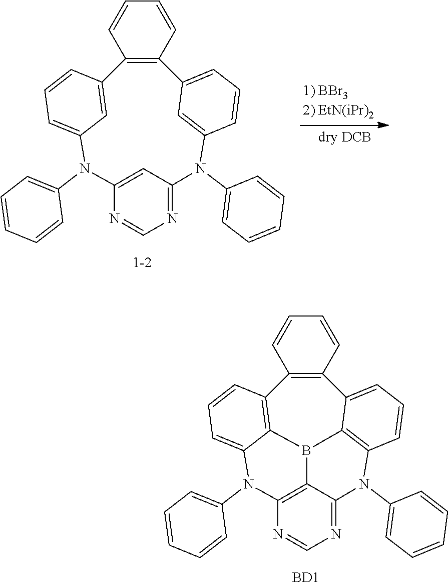

To a degassed 50 mL two-necked flask were added 1.10 g (2.25 mmol) of the compound 1-2 and 20 ml of dehydrated dichlorobenzene, and the mixture was made into a solution. After 9 ml (9 mmol) of a 1 M solution of boron tribromide was added thereto, the mixture was left stirring for 5 minutes, and then was stirred at a bath temperature of 180° C. for 2 hours. The flask was placed in a bath of iced water to be at 0° C., followed by drop-by-drop addition of 2.35 ml (13.5 mmol) of diisopropylethylamine. The mixture was left stirring for 5 minutes and then stirred at room temperature for 30 minutes. The mixture was heated up to 120° C. and stirred with heating overnight. Cooled down to room temperature, the reaction mixture was applied to a short pad of silica gel and then was purified by silica gel column chromatography. Purification by recrystallization gave 290 mg (0.58 mmol) of the compound BD1 in 26% yield.

FD-MS (field desorption mass spectrometry) showed a mass spectrum of m/z 496, by which the obtained compound BD1 was identified as a compound of the above structural formula.

### Example 2

### Synthesis of the Boron-Containing Compound BD2

### (i) Synthesis of the Compound 2-2

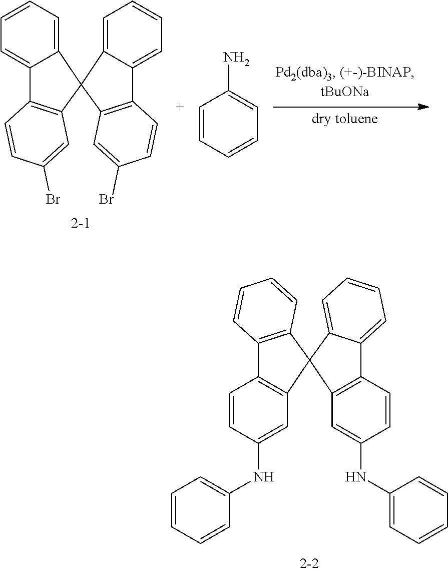

To a 300 mL four-necked flask containing a stir bar were added 7.76 g (20.0 mmol) of the compound 2-1 and 4.48 g (48 mmol) of aniline, 10.76 g (112 mmol) of sodium tert-butoxide and 200 ml of dehydrated toluene. After the mixture was bubbled with nitrogen for 1 hour, 740 mg (0.80 mmol) of tris(dibenzylideneacetone)dipalladium (0) and 1.12 g (1.8 mmol) of (±)−BINAP were added thereto, and the resulting mixture was refluxed with stirring overnight. TLC confirmed the disappearance of the starting materials in the reaction mixture. After filtering out insoluble matter with celite, the filtrate was concentrated. The collected solid was purified by silica gel column chromatography to give 8.18 g (16.4 mmol) of the compound 2-2 in 82% yield.

### (ii) Synthesis of the Compound 2-3

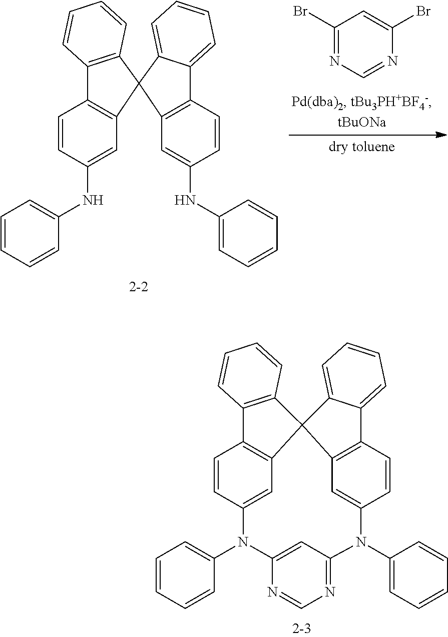 [SMILES: c1ccc(Nc2ccc3c(c2)C2(c4ccccc4-3)c3ccccc3-c3ccc(Nc4ccccc4)cc32)cc1 ; Brc1cc(Br)ncn1 ; c1ccc(N2c3ccc4c(c3)C3(c5ccccc5-4)c4ccccc4-c4ccc(cc43)N(c3ccccc3)c3cc2ncn3)cc1]

To a 1000 mL four-necked flask with a nitrogen introduction pipe on were added 4.99 g (10 mmol) of the compound 2-2, 2.38 g (10 mmol) of 4,6-dibromopyrimidine, 2.88 g (30 mmol) of sodium tert-butoxide and 1000 ml of dehydrated toluene, and the mixture was bubbled with nitrogen for 1 hour. After 230 mg (0.4 mmol) of bis(dibenzylideneacetone)palladium (0) and 93 mg (0.32 mmol) of tri-tert-butylphophonium tetrafluoroborate were added thereto, the mixture was refluxed with stirring overnight. TLC confirmed the disappearance of the starting materials in the reaction mixture. The reaction mixture was extracted with toluene, and the resulting extract was washed with brine and dried with MgSO₄. The solvent was removed by evaporation, and the residue was purified by silica gel column chromatography to give 2.41 g (4.2 mmol) of the compound 2-3 in 42% yield.

(iii) Synthesis of the compound BD2 (boron-containing compound)

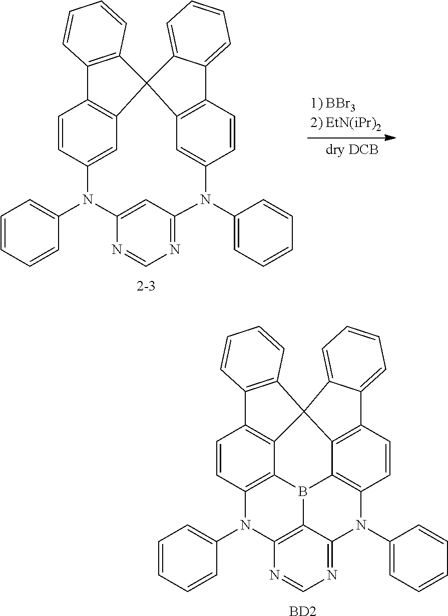

To a degassed 50 mL two-necked flask were added 1.29 g (2.25 mmol) of the compound 2-3 and 20 ml of dehydrated dichlorobenzene, and the mixture was made into a solution. After 9 ml (9 mmol) of a 1 M solution of boron tribromide was dripped there, the mixture was left stirring for 5 minutes, and then was stirred at a bath temperature of 180° C. for 2 hours. The flask was placed in a bath of iced water to be at 0° C., followed by drop-by-drop addition of 2.35 ml (13.5 mmol) of diisopropylethylamine. The mixture was left stirring for 5 minutes and then stirred at room temperature for 30 minutes. Then heated up to 120° C., the mixture was stirred with heating overnight. Cooled down to room temperature, the reaction mixture was applied to a short pad of silica gel and then purified by silica gel column chromatography. Purification by recrystallization gave 275 mg (0.47 mmol) of the compound BD2 in 21% yield.

FD-MS (field desorption mass spectrometry) showed a mass spectrum of m/z 582, by which the obtained compound BD2 was identified as a compound of the above structural formula.

### Example 3

### Synthesis of the Boron-Containing Compound BD3

### (i) Synthesis of the Compound 2-4

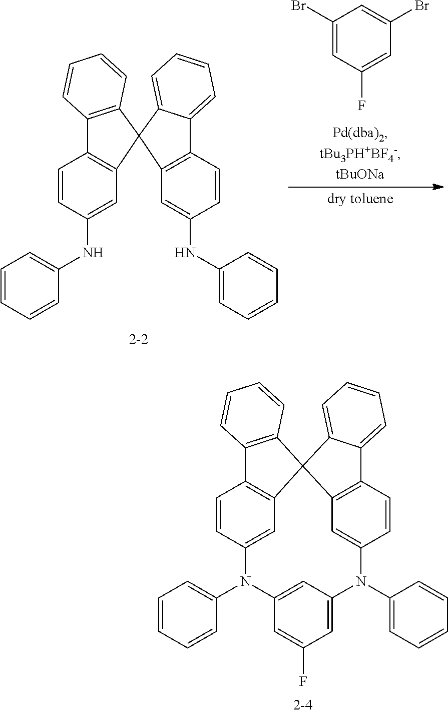 [SMILES: c1ccc(Nc2ccc3c(c2)C2(c4ccccc4-3)c3ccccc3-c3ccc(Nc4ccccc4)cc32)cc1 ; Fc1cc(Br)cc(Br)c1 ; Fc1cc2cc(c1)N(c1ccccc1)c1ccc3c(c1)C1(c4ccccc4-c4ccc(cc41)N2c1ccccc1)c1ccccc1-3]

To a 1000 mL four-necked flask with a nitrogen introduction pipe on were added 4.99 g (10 mmol) of the compound 2-2, 2.54 g (10 mmol) of 1,3-dibromo-5-fluorobenzene, 2.88 g (30 mmol) of sodium tert-butoxide and 1000 ml of dehydrated toluene, and the mixture was bubbled with nitrogen for 1 hour. After 230 mg (0.4 mmol) of bis(dibenzylideneacetone)palladium (0) and 93 mg (0.32 mmol) of tri-tert-butylphophonium tetrafluoroborate were added thereto, the mixture was refluxed with stirring overnight. TLC confirmed the disappearance of the starting materials in the reaction mixture. The reaction mixture was extracted with toluene, and the resulting extract was washed with brine and dried with MgSO₄. The solvent was removed by evaporation, and the residue was purified by silica gel column chromatography to give 2.54 g (4.3 mmol) of the compound 2-4 in 43% yield.

### (ii) Synthesis of the Compound BD3 (Boron-Containing Compound)

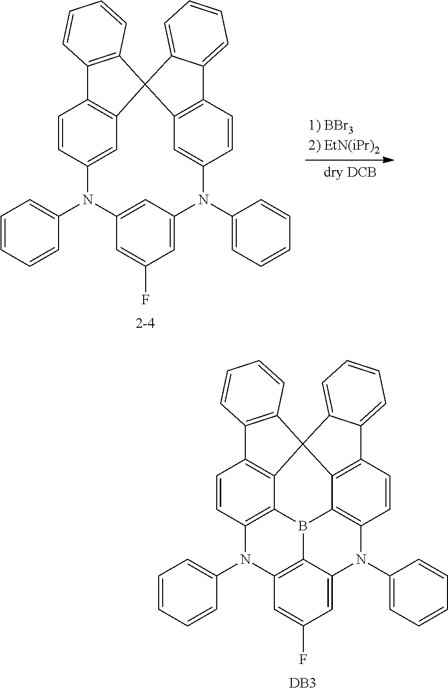

To a degassed 50 mL two-necked flask were added 1.33 g (2.25 mmol) of the compound 2-4 and 20 ml of dehydrated dichlorobenzene, and the mixture was made into a solution. After 9 ml (9 mmol) of a 1 M solution of boron tribromide was dripped there, the mixture was left stirring for 5 minutes, and then was stirred at a bath temperature of 180° C. for 2 hours. The flask was placed in a bath of iced water to be at 0° C., followed by drop-by-drop addition of 2.35 ml (13.5 mmol) of diisopropylethylamine. The mixture was left stirring for 5 minutes and then stirred at room temperature for 30 minutes. Then heated up to 120° C., the mixture was stirred with heating overnight. Cooled down to room temperature, the reaction mixture was applied to a short pad of silica gel and then purified by silica gel column chromatography. Purification by recrystallization gave 417 mg (0.70 mmol) of the compound BD3 in 31% yield.

FD-MS (field desorption mass spectrometry) showed a mass spectrum of m/z 598, by which the obtained compound BD3 was identified as a compound of the above structural formula.

### Example 4

### Synthesis of the boron-containing compound BD4

(i) Synthesis of the compound 3-2

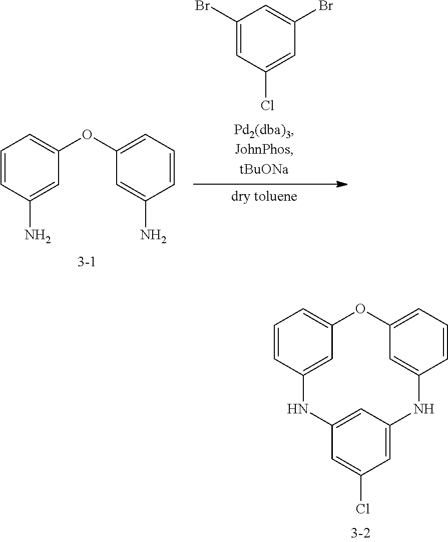 [SMILES: Clc1cc(Br)cc(Br)c1 ; Nc1cccc(Oc2cccc(N)c2)c1 ; Clc1cc2cc(c1)Nc1cccc(c1)Oc1cccc(c1)N2]

To a 1000 mL four-necked flask with a nitrogen introduction pipe on were added 2.00 g (10 mmol) of the compound 3-1, 2.70 g (10 mmol) of 1,3-dibromo-5-chlorobenzene, 2.88 g (30 mmol) of sodium tert-butoxide and 1000 ml of dehydrated toluene, and the mixture was bubbled with nitrogen for 1 hour. After 366 mg (0.4 mmol) of tris(dibenzylideneacetone)dipalladium (0) and 95 mg (0.32 mmol) of JohnPhos were added thereto, the mixture was refluxed with stirring overnight. TLC confirmed the disappearance of the starting materials in the reaction mixture. The reaction mixture was extracted with toluene, and the resulting extract was washed with brine and dried with MgSO₄. The solvent was removed by evaporation, and the residue was purified by silica gel column chromatography to give 988 mg (3.2 mmol) of the compound 3-2 in 32% yield.

### (ii) Synthesis of the Compound 3-3

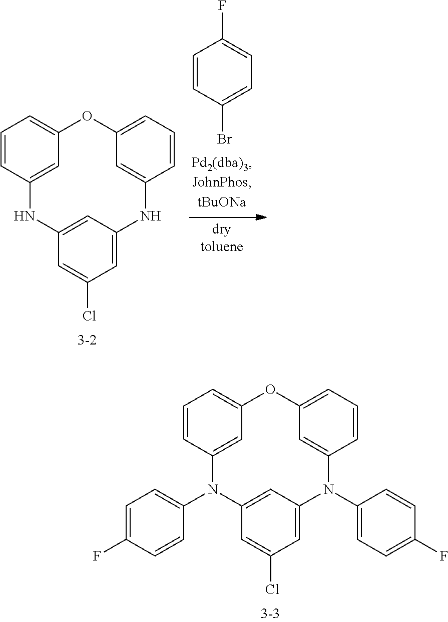 [SMILES: Clc1cc2cc(c1)Nc1cccc(c1)Oc1cccc(c1)N2 ; Fc1ccc(Br)cc1 ; Fc1ccc(N2c3cccc(c3)Oc3cccc(c3)N(c3ccc(F)cc3)c3cc(Cl)cc2c3)cc1]

To a 50 mL four-necked flask containing a stir bar were added 988 mg (3.2 mmol) of the compound 3-2, 1.34 g (7.7 mmol) of 4-bromofluorobenzene, 1.72 g (17.9 mmol) of sodium tert-butoxide and 30 ml of dehydrated toluene, and the mixture was bubbled with nitrogen for 1 hour. After 117 mg (0.13 mmol) of tris(dibenzylideneacetone)dipalladium (0) and 78 mg (0.26 mmol) of JohnPhos were added thereto, the mixture was refluxed with stirring overnight. TLC confirmed the disappearance of the starting materials in the reaction mixture. After filtering out insoluble matter with celite, the filtrate was concentrated. The collected solid was purified by silica gel column chromatography to give 1.54 g (3.1 mmol) of the compound 3-3 in 97% yield.

(iii) Synthesis of the Compound 3-4

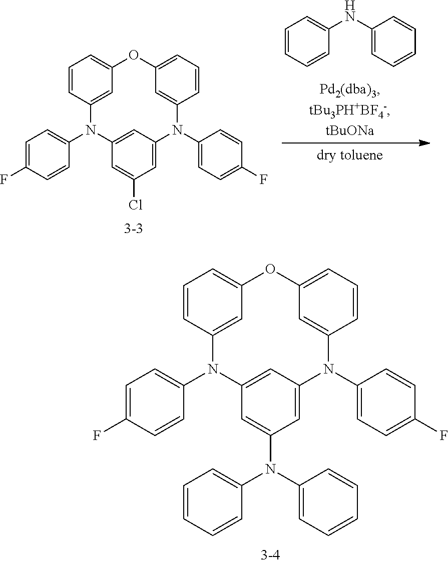 [SMILES: Fc1ccc(N2c3cccc(c3)Oc3cccc(c3)N(c3ccc(F)cc3)c3cc(Cl)cc2c3)cc1 ; c1ccc(Nc2ccccc2)cc1 ; Fc1ccc(N2c3cccc(c3)Oc3cccc(c3)N(c3ccc(F)cc3)c3cc(N(c4ccccc4)c4ccccc4)cc2c3)cc1]

To a 50 mL four-necked flask containing a stir bar were added 1.54 g (3.1 mmol) of the compound 3-3, 630 mg (3.7 mmol) of diphenylamine, 890 mg (9.3 mmol) of sodium tert-butoxide, and 30 ml of dehydrated toluene, and the mixture was bubbled with nitrogen for 1 hour. After 117 mg (0.13 mmol) of tris(dibenzylideneacetone)dipalladium (0) and 75 mg (0.26 mmol) of tri-tert-butylphophonium tetrafluoroborate were added thereto, the mixture was refluxed with stirring overnight. TLC confirmed the disappearance of the starting materials in the reaction mixture. After filtering out insoluble matter with celite, the filtrate was concentrated. The collected solid was purified by silica gel column chromatography to give 1.85 g (2.9 mmol) of the compound 3-4 in 95% yield.

### (iv) Synthesis of the Compound BD4 (Boron-Containing Compound)

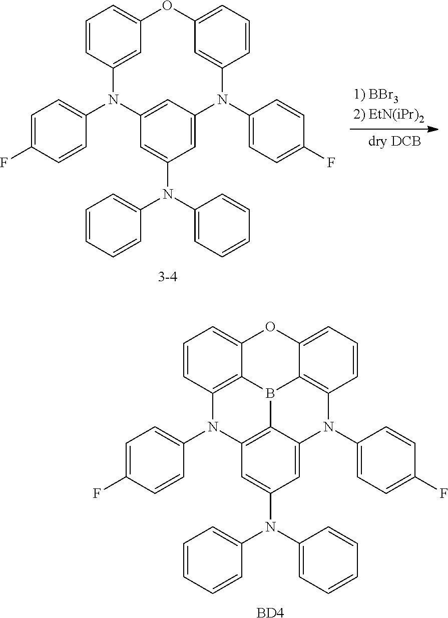

To a degassed 50 mL two-necked flask were added 1.42 g (2.25 mmol) of the compound 3-4 and 20 ml of dehydrated dichlorobenzene, and the mixture was made into a solution. After 9 ml (9 mmol) of a 1 M solution of boron tribromide was dripped there, the mixture was left stirring for 5 minutes, and then was stirred at a bath temperature of 180° C. for 2 hours. The flask was placed in a bath of iced water to be at 0° C., followed by drop-by-drop addition of 2.35 ml (13.5 mmol) of diisopropylethylamine. The mixture was left stirring for 5 minutes and then stirred at room temperature for 30 minutes. Then heated up to 120° C., the mixture was stirred with heating overnight. Cooled down to room temperature, the reaction mixture was applied to a short pad of silica gel and then purified by silica gel column chromatography. Purification by recrystallization gave 502 mg (0.79 mmol) of the compound BD4 in 35% yield.

FD-MS (field desorption mass spectrometry) showed a mass spectrum of m/z 637, by which the obtained compound BD4 was identified as a compound of the above structural formula.

### Example 5

### Synthesis of the Boron-Containing Compound BD5

### (i) Synthesis of the Compound 4-2

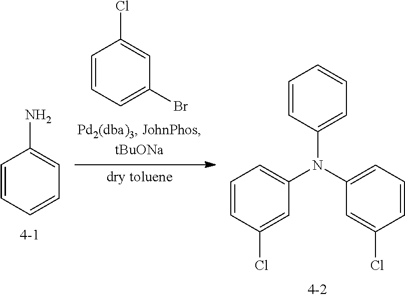 [SMILES: Nc1ccccc1 ; Clc1cccc(Br)c1 ; Clc1cccc(N(c2ccccc2)c2cccc(Cl)c2)c1]

To a 300 mL four-necked flask containing a stir bar were added 1.86 g (20 mmol) of the compound 4-1, 4.59 g (24 mmol) of 1-bromo-3-chlorobenzene, 11.53 g (120 mmol) of sodium tert-butoxide, and 200 ml of dehydrated toluene, and the mixture was bubbled with nitrogen for 1 hour. After 732 mg (0.8 mmol) of tris(dibenzylideneacetone)dipalladium (0) and 477 mg (1.6 mmol) of JohnPhos were added thereto, the mixture was refluxed with stirring overnight. TLC confirmed the disappearance of the starting materials in the reaction mixture. After filtering out insoluble matter with celite, the filtrate was concentrated. The collected solid was purified by silica gel column chromatography to give 4.27 g (13.6 mmol) of the compound 4-2 in 68% yield.

### (ii) Synthesis of the Compound 4-3

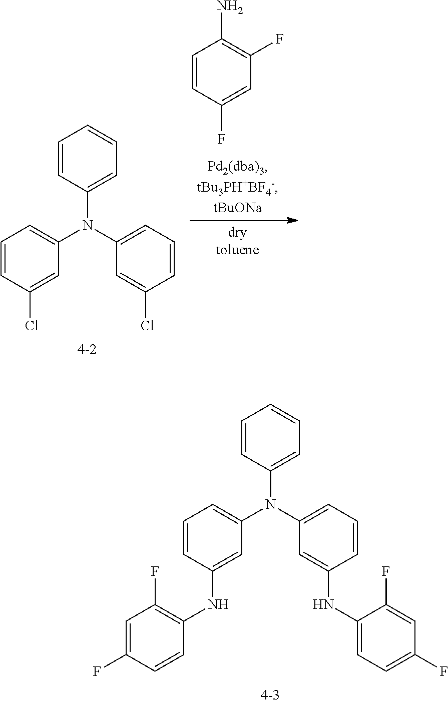 [SMILES: Clc1cccc(N(c2ccccc2)c2cccc(Cl)c2)c1 ; Nc1ccc(F)cc1F ; Fc1ccc(Nc2cccc(N(c3ccccc3)c3cccc(Nc4ccc(F)cc4F)c3)c2)c(F)c1]

To a 200 mL four-necked flask containing a stir bar were added 4.27 g (13.6 mmol) of the compound 4-2, 4.21 g (32.6 mmol) of 2,4-difluoroaniline, 7.32 g (76.2 mmol) of sodium tert-butoxide and 140 ml of dehydrated toluene, and the mixture was bubbled with nitrogen for 1 hour. After 498 mg (0.54 mmol) of tris(dibenzylideneacetone)dipalladium (0) and 313 mg (1.08 mmol) of tri-tert-butylphophonium tetafluoroborate were added thereto, the mixture was refluxed with stirring overnight. TLC confirmed the disappearance of the starting materials in the reaction mixture. After filtering out insoluble matter with celite, the filtrate was concentrated. The collected solid was purified by silica gel column chromatography to give 5.16 g (10.3 mmol) of the compound 4-3 in 76% yield.

(iii) Synthesis of the Compound 4-4

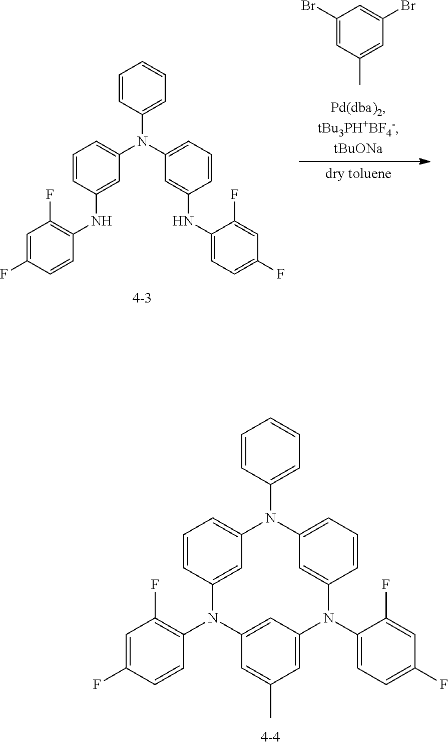

To a 1000 mL four-necked flask with a nitrogen introduction pipe on were added 5.00 g (10 mmol) of the compound 4-3, 2.50 g (10 mmol) of 3,5-dibromotoluene, 2.88 g (30 mmol) of sodium tert-butoxide and 1000 ml of dehydrated toluene, and the mixture was bubbled with nitrogen for 1 hour. After 230 mg (0.4 mmol) of bis(dibenzylideneacetone)palladium (0) and 93 mg (0.32 mmol) of tri-tert-butylphosphonium tetrafluoroborate were added thereto, the mixture was refluxed with stirring overnight. TLC confirmed the disappearance of the starting materials in the reaction mixture. The reaction mixture was extracted with toluene, and the resulting extract was washed with brine and dried with MgSO₄. The solvent was removed by evaporation, and the residue was purified by silica gel column chromatography to give 2.23 g (3.8 mmol) of the compound 4-4 in 38% yield.

### (iv) Synthesis of the Compound BD5 (Boron-Containing Compound)

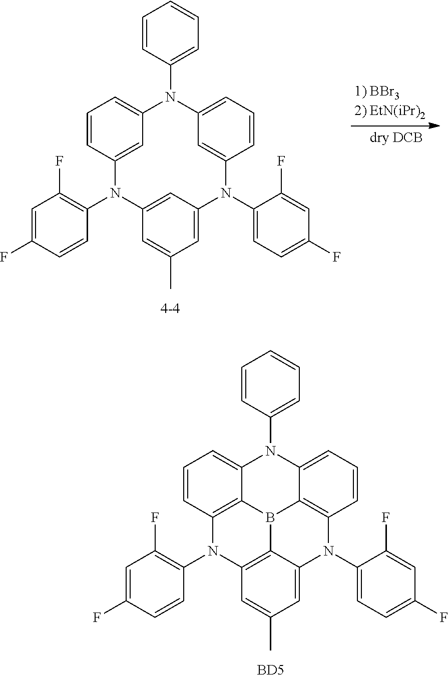

To a degassed 50 mL two-necked flask were added 1.32 g (2.25 mmol) of the compound 4-4 and 20 ml of dehydrated dichlorobenzene, and the mixture was made into a solution. After 9 ml (9 mmol) of a 1 M solution of boron tribromide was dripped there, the mixture was left stirring 5 minutes, and then was stirred at a bath temperature of 180° C. for 2 hours. The flask was placed in a bath of iced water to be at 0° C., followed by drop-by-drop addition of 2.35 ml (13.5 mmol) of diisopropylethylamine. The mixture was left stirring for 5 minutes and then stirred at room temperature for 30 minutes. Then heated up to 120° C., the mixture was refluxed with stirring overnight. Cooled down to room temperature, the reaction mixture was applied to a short pad of silica gel and then purified by silica gel column chromatography. Purification by recrystallization gave 442 mg (0.74 mmol) of the compound BD5 in 33% yield.

FD-MS (field desorption mass spectrometry) showed a mass spectrum of m/z 595, by which the obtained compound BD5 was identified as a compound of the above structural formula.

### Manufacturing and Evaluation of EL Device

### Example 6

A glass substrate of 26 mm×28 mm×0.7 mm (manufactured by Opto Science Inc.,), on which ITO was sputtered to a thickness of 180 nm and then polished to 150 nm, was used as a transparent support substrate.

The transparent support substrate was fixed to a substrate holder of a commercially available deposition apparatus (manufactured by Showa Shinku Co., Ltd.). The deposition apparatus was equipped with a vapor deposition boat made of molybdenum containing HATCN (HIM; hole injection material), a vapor deposition boat made of molybdenum containing α-NPD (HTM; hole transport material), a vapor deposition boat made of molybdenum containing EBL (electron barrier material), a vapor deposition boat made of molybdenum containing BH1 (host), a vapor deposition boat made of molybdenum containing the compound BD1 synthesized in Example 1, a vapor deposition boat made of molybdenum containing HBL (hole barrier material), a vapor deposition boat made of molybdenum containing NBPhen (ETM; electron transport material), a vapor deposition boat made of molybdenum containing LiF, and a vapor deposition boat made of tungsten containing aluminum. The structural formula for each of the materials is shown below.

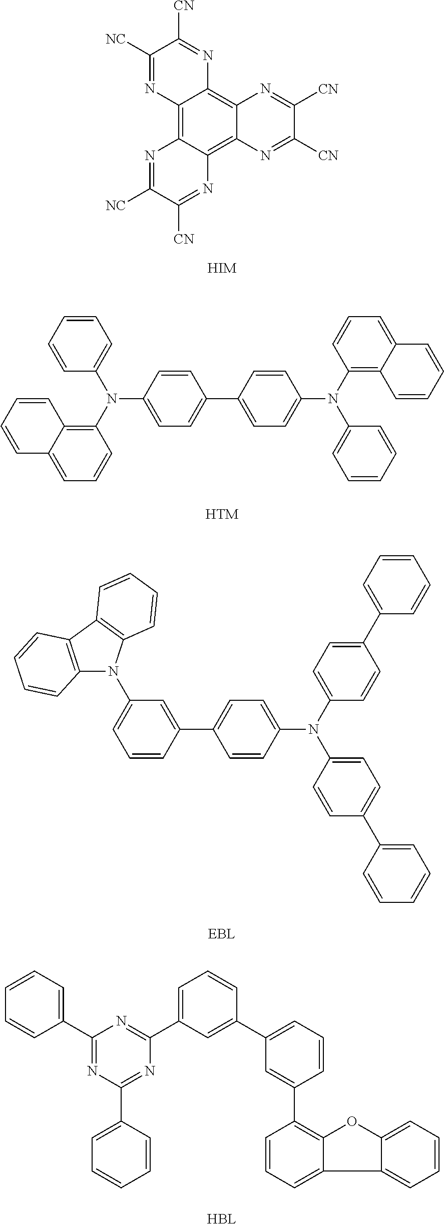

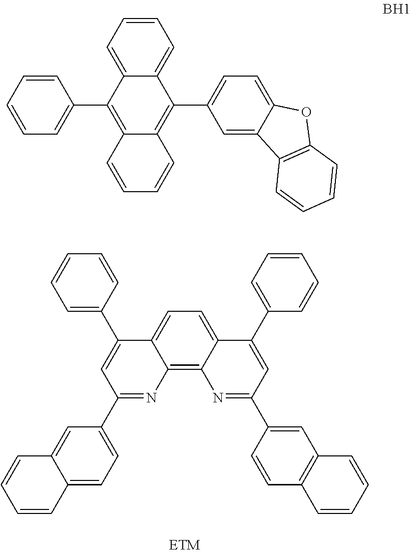

Each layer was successively formed on the ITO film of the transparent support substrate as described below. The inside pressure of a vacuum chamber was reduced to 5×10⁻⁴ Pa, and first of all, the vapor deposition boat containing HIM was heated, so that HIM vaporized and formed the hole injection layer 2 with a thickness of 5 nm. Next, the vapor deposition boat containing HTM was heated, so that HTM vaporized and formed the hole transport layer 3 with a thickness of 105 nm. The vapor deposition boat containing EBL was heated, so that EBL vaporized and formed the electron barrier layer 4 with a thickness of 20 nm.

Next, the vapor deposition boat containing BH1 and the vapor deposition boat containing the compound BD1 were heated at the same time, and the light-emitting layer 5 was vapor deposited with a thickness of 25 nm. The vapor deposition rate was controlled so as to give a weight ratio of BH1 and the compound BD1 at approximately 97:3.

Then the vapor deposition boat containing HBL was heated, so that HBL vaporized and formed the hole barrier layer 6 with a thickness of 20 nm. The vapor deposition boat containing ETM was heated, so that ETM vaporized and formed the electron transport layer 7 with a thickness of 10 nm.

The vapor deposion rate of each layer was 0.01 to 2 nm/s.

Then the vapor deposition boat containing LiF as a material for the electron injection layer 8 was heated, so that LiF was vapor deposited to a thickness of 1 nm at a vapor deposition rate of 0.01 to 0.1 nm/s. The vapor deposition boat containing aluminum was heated, and the cathode 9 was formed with a thickness of 100 nm at a vapor deposition rate of 0.01 to 2 nm/s, which resulted in the OLED.

When the direct current was applied on the OLED with an ITO electrode as the anode 1 and a LiF/aluminum electrode as the cathode 9, blue light emission was obtained.

The OLED was driven by a constant current at an initial luminance of 1000 nit, and the time was measured until the luminance reached 95%.

### Example 7

The EL device was prepared in a manner similar to Example 6, except that the compound BD2 synthesized in Example 2 was used instead of the compound BD1.

### Example 8

The EL device was prepared in a manner similar to Example 6, except that the compound BD3 synthesized in Example 3 was used instead of the compound BD1.

### Example 9

The EL device was prepared in a manner similar to Example 6, except that the compound BD4 synthesized in Example 4 was used instead of the compound BD1.

### Example 10

The EL device was prepared in a manner similar to Example 6, except that the compound BD5 synthesized in Example 5 was used instead of the compound BD1.

### Comparative Example 1

The EL device was prepared in a manner similar to Example 6, except that the compound represented by the following structural formula was used instead of the compound BD1.

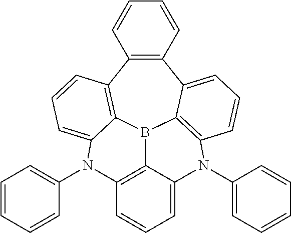 [SMILES: c1ccc(N2c3cccc4c3B3c5c(cccc5N(c5ccccc5)c5cccc2c53)-c2ccccc2-4)cc1]

When the direct current was applied on the EL device with an ITO electrode as the anode 1 and a LiF/aluminum electrode as the cathode 9, blue light emission was observed.

The EL device was driven by a constant current at an initial luminance of 1000 nit, and the time was measured until the luminance reached up to 95%.

TABLE 1

| | | Relative Value, based on |
|---|---|---|
| | | 100 of the measurement |
| | Peak Wavelength (nm) | time in Comp. Ex. 1 |
| Ex. 6 | 450 | 135 |
| Ex. 7 | 453 | 148 |
| Ex. 8 | 459 | 163 |
| Ex. 9 | 451 | 122 |
| Ex. 10 | 449 | 118 |
| Comp. Ex. 1 | 473 | 100 |

The results confirm that the compounds of the present invention have shorter wavelength and maintain longer lifetime of blue light emission than those of prior arts.

What is claimed is:

1. A boron-containing compound having a structure represented by the following general formula (1): 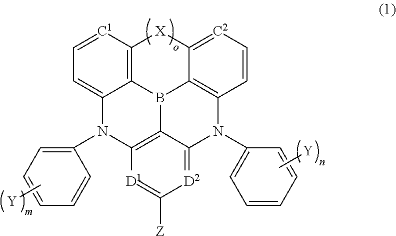
X is —BAr—, —CR¹R²—, —NAr—, —O—, —SiR³R⁴— or —S—,
wherein Ar is an aryl group;
R¹, R², R³ and R⁴ are each independently a hydrogen atom, an alkyl group having 1 to 6 carbon atoms, an alkoxy group having 1 to 6 carbon atoms, an amino group or an aryl group having 5 to 30 core atoms, and R¹ and R², or R³ and R⁴ may join each other to form a ring;
o is 1 or 2;
C¹ and C² each are a carbon atom or an aryl carbon atom and may form a ring with X and the neighboring carbon atom together;
Y is a fluoro group; 0≤m+n≤10 wherein m and n are an integer of 0 to 5;
D¹ and D² are each independently a carbon atom or a nitrogen atom;
Z is a hydrogen atom, an alkyl group having 1 to 6 carbon atoms, an alkoxy group having 1 to 6 carbon atoms, a fluoro group or an amino group.

2. The boron-containing compound according to claim 1, wherein in the general formula (1),
D¹ and D² both are carbon atoms;
Y is a fluoro group;
1≤m+n≤10 wherein m and n are an integer of 0 to 5; and
Z is an alkyl group having 1 to 6 carbon atoms, an alkoxy group having 1 to 6 carbon atoms, a fluoro group or an amino group.

3. The boron-containing compound according to claim 1, wherein in the general formula (1),
at least one of D¹ and D² is a nitrogen atom;
Y is a fluoro group;
0≤m+n≤10 wherein m and n are an integer of 0 to 5; and
Z is a hydrogen atom.

4. An organic light-emitting diode comprising the boron-containing compound according to claim 1 in the light-emitting zone.

5. An organic light-emitting diode comprising 0.1 to 20 wt % of the boron-containing compound according to claim 1 in the light-emitting layer.
